(19) United States
(12) Patent Application Publication
(10) Pub. No.: US 2006/0145347 A1
(43) Pub. Date: Jul. 6, 2006

(54) Semiconductor device and method for fabricating the same

(76) Inventor: Kazuhiko Aida, Osaka (JP)

Correspondence Address: PANASONIC PATENT CENTER;c/o MCDERMOTT WILL & EMERY LLP, 600 13TH STREET, NW, WASHINGTON, DC, 20005-3096, US

(21) Appl. No.: 11/198,224

(22) Filed: Aug. 8, 2005

(30) Foreign Application Priority Data
Jan. 6, 2005 (JP) 2005-001857

(51) Int. Cl. H01L 23/52; H01L 21/4763

(52) U.S. Cl. 257/758; 438/622

(57) ABSTRACT

A semiconductor device includes a semiconductor element formed on a semiconductor substrate, a first interconnect formed over the semiconductor substrate so as to be electrically connected with the semiconductor element, and a second interconnect formed over the first interconnect with an interlevel insulation film made of an insulator having a lower dielectric constant than a dielectric constant of silicon oxide interposed between the first interconnect and the second interconnect. Furthermore, the semiconductor device includes a first dummy interconnect formed in part of the semiconductor substrate located in the vicinity of the first interconnect or the second interconnect.

### CROSS-REFERENCE TO RELATED APPLICATION

The disclosure of Japanese Patent Application No. 2005-1857 filed on Jan. 6, 2005 including specification, drawings and claims are incorporated herein by reference in its entirety.

### BACKGROUND OF THE INVENTION

The present invention relates to a semiconductor device and a method for fabricating the same and more particularly relates to a semiconductor device using a so-called low dielectric constant insulation film (low-K film) for an interlevel insulation film between interconnects forming a multi-layer interconnect structure.

In recent years, with increase in the degree of integration of elements in a semiconductor integrated circuit device and the operation speed thereof, progress has been made in techniques using, as an insulation film for providing insulation between interconnects in a multi-layer interconnect, a low dielectric constant insulation film having a smaller dielectric constant than that of silicon oxide. With such a low dielectric constant insulation film, a capacitance between interconnects can be reduced. As a result, a signal delay can be prevented and also the high speed operation of a semiconductor integrated circuit can be achieved.

However, it is a problem of a low dielectric constant insulation film such as silicon oxide (SiOC) containing carbon that chemical, mechanical and thermal stability is lower than that of a known silicon dioxide (SiO₂) film.

To cope with this problem, as an example of a method for improving the intensity of a semiconductor integrated circuit device using a low dielectric constant insulation film as an interlevel insulation film, a technique in which a seal ring structure formed using a similar material to an material of a multi-layer interconnect and a via plug is provided in a peripheral portion of a chip formation region in each interlevel insulation film has been conventionally used.

For example, as shown in FIG. 10A and a partial enlarged plan view of FIG. 10B, a seal ring structure 102 is formed in an inner peripheral portion of a scribe region 101 in a semiconductor substrate (semiconductor wafer) 100.

As shown in FIG. 11, the seal ring structure 102 has a multi-layer structure including the same conductive members as those of an interconnect formed in order over a doped layer 106 interposed between isolation regions 105 formed in upper part of the semiconductor substrate 100.

Specifically, the seal ring structure 102 includes a contact plug 111 formed in a first interlevel insulation film 110, a first conductor layer 141 formed in a second interlevel insulation film 122, a second conductor layer 142 formed in a fourth interlevel insulation film 124, a third conductor layer 143 formed in a sixth interlevel insulation film 126, and a fourth conductor layer 144 formed in an eighth interlevel insulation film 128.

A first connection section 151 is provided in the third interlevel insulation film 123 between the first conductor layer 141 and the second conductor layer 142. A second connection section 152 is provided in a fifth interlevel insulation film 125 between the second conductor layer 142 and the third conductor layer 143. And a third connection section 153 is provided in a seventh interlevel insulation film 127 between the third conductor layer 143 and the fourth conductor layer 144.

In this case, the first interlevel insulation film 110 is formed of silicon oxide and each of the second through eighth interlevel insulation films 122 through 128 is formed of a low dielectric constant insulation film. Moreover, an etching stopper film 130 is provided between adjacent two of the interlevel insulation films. Furthermore, an insulation film 150 having moisture resistance and a polyimide film 151 as a protection film are formed over the eighth insulation film 128.

As a low dielectric constant insulation film for forming each of the second through eighth interlevel insulation films 122 through 128, in general, an organic film is used in many cases. However, it has been known that an organic film has a low density and thus is poor in chemical stability, mechanical strength, adhesion and thermal stability.

Thus, in a known semiconductor integration circuit device using a low dielectric constant insulation film, the seal ring structure 102 and the insulation film 151 having moisture resistance are provided, so that a device formation region 103a in the semiconductor substrate 100 is protected from effects of moisture from the outside and chemicals such as ions. Therefore, electrical characteristics of the semiconductor integrated circuit device can be kept stable for a long period of time.

Furthermore, the seal ring structure 102 has the function of keeping a crack that is prone to be generated in dicing along a dicing line 104 due to low mechanical strength of the low dielectric constant insulation films only within an outer edge portion of a chip region 103, so that the crack does not reach the device formation region 103a located inside of the seal ring structure 102, as shown in FIGS. 10A and 10B.

As described above, the seal ring structure 102 has the effect of protecting the device formation region 103a when or after the first insulation film 110 and the second through eighth interlevel insulation films 122 through 128, the first through fourth conductor layers 141 through 144, the first through third connection sections 151 through 153 and the moisture resistance insulation film 150 are formed over the semiconductor substrate 100 and then the semiconductor integration circuit device is divided into chips by dicing.

However, the effects of the seal ring structure 102 in which the known semiconductor integrated circuit device is provided are not exhibited before the semiconductor substrate (semiconductor wafer) 100 is cut along the dicing line 104 to be divided into individual semiconductor chips. Furthermore, a region protected by the seal ring structure 102 is limited to part of the device formation region 103a located in vicinity of an inner peripheral portion of the seal ring structure 102.

In process steps of a semiconductor integrated circuit, different phenomena, i.e., the generation of a mechanical stress in polishing represented by chemical mechanical polishing (CMP) and the generation of heat when a resultant semiconductor device is in operation. Moreover, a low dielectric constant insulation film forming the second interlevel insulation film 122 and the like has low resistance against mechanical stress and heat. This becomes a cause of reduction in reliability of a semiconductor integrated circuit.

### SUMMARY OF THE INVENTION

An object of the present invention is to solve the above-described problems to improve mechanical and thermal resistance in a semiconductor device using an interlevel insulation film formed of a low dielectric constant insulator.

To achieve the object, according to the present invention, a semiconductor device using an interlevel insulation film formed of a low dielectric constant insulator is formed so as to have a configuration in which a dummy interconnect region which does not effect the operation of the semiconductor device is formed in part of the interlevel insulation film located in the vicinity of the semiconductor device.

Specifically, a semiconductor device according to the present invention is characterized by including: a semiconductor element formed on a semiconductor region; a first interconnect formed over the semiconductor region and electrically connected to the semiconductor element; a second interconnect formed over the first interconnect with an interlevel insulation film made of an insulator having a lower dielectric constant than a dielectric constant of silicon oxide interposed between the first interconnect and the second interconnect; and a first dummy interconnect formed on part of the semiconductor region located in the vicinity of the first interconnect or the second interconnect.

In the semiconductor device of the present invention, in forming an interconnect, when the interlevel insulation film made of an insulator having a lower dielectric constant than a dielectric constant of silicon oxide and a metal film for forming an interconnect are polished together, the mechanical strength of an interlevel insulation film, which is a relatively small strength, can be improved. As a result, resistance against mechanical stress in polishing can be increased. Moreover, with the dummy interconnect provided in the interlevel insulation film, heat conductivity while the semiconductor element is in operation becomes excellent. Therefore, a long-term reliability of the semiconductor device is improved.

It is preferable that the semiconductor device of the present invention further includes a contact plug for connecting the first dummy interconnect and the semiconductor region. Thus, heat generated from the first interconnect or the second interconnect can be directly conducted to the semiconductor region, for example, the semiconductor substrate. Thus, resistance against heat is further improved.

It is preferable that the semiconductor device of the present invention further includes a pad electrode electrically connected with the first dummy interconnect. Thus, heat generated from the first interconnect or the second interconnect can be directly conducted to the pad electrode and, furthermore, to the outside. Therefore, resistance against heat can be improved.

In the semiconductor device of the present invention, it is preferable that the first dummy interconnect is formed along the first interconnect or the second interconnect and the length of a side of the first dummy interconnect is 100 μm or less.

Thus, the dummy interconnect has a relatively small length and therefore can be disposed in an arbitrary location around the semiconductor element. As a result, the integration density of the semiconductor element is not reduced and mechanical and thermal resistances can be increased to a maximum level.

In the semiconductor device of the present invention, it is preferable that the first dummy interconnect is formed by the side of the first interconnect so as to be located adjacent to the first interconnect, and the semiconductor device further includes a second dummy interconnect formed over the first dummy interconnect with an interlevel insulation film interposed between the first dummy interconnect and the second dummy interconnect. Thus, as the first interconnect and the second interconnect, with the same number of dummy interconnects as the number of regular interconnect layers provided, the present invention can be reliably applied to a semiconductor device having a multi-layer interconnect structure.

In such a case, it is preferable that the first dummy interconnect and the second dummy interconnect are connected to each other via a dummy connection section. Thus, resistance against mechanical stress and heat is further improved.

Moreover, in this case, it is preferable that the second interconnect and a connection portion for connecting the first interconnect and the second interconnect are formed as a unit and the second dummy interconnect and the dummy connection portion are formed as a unit. Thus, an interconnect structure including the dummies can be formed into a so-called dual damascene structure.

In the semiconductor device of the present invention, the first dummy interconnect may be electrically floating. The dummy interconnect of the present invention does not have to be connected to the semiconductor region (semiconductor substrate), i.e., in a state in which an electric potential is fixed. When a sufficient area can not be ensured for a region in which a dummy connection portion is to be provided, the dummy interconnect may be made floating.

In the semiconductor device of the present invention, it is preferable that the first interconnect, the second interconnect and the first dummy interconnect are formed of a metal containing copper as a main component.

In the semiconductor device of the present invention, it is preferable that the interlevel insulation film is formed of silicon oxide containing carbon, fluorine or nitride. Thus, the interlevel insulation film contains silicon oxide as a main component, so that a semiconductor process using silicon can be easily adopted.

In the semiconductor device of the present invention, it is preferable that the first dummy interconnect is formed in the inside of a seal ring formed along an inner peripheral portion of a scribe region of the semiconductor region. In this structure, resistance against stress and heat generated in polishing can be remarkably improved.

A method for fabricating a semiconductor device according to the present invention is characterized by including the steps of: a) forming, on a semiconductor region, a first interlevel insulation film of an insulator having a lower dielectric constant than a dielectric constant of silicon oxide; b) selectively forming, in an upper portion of the first interlevel insulation film, a first interconnect formation groove and a first dummy interconnect formation groove so that the first dummy interconnect formation groove is located in the vicinity of the first interconnect formation groove; c) forming a first metal film over the first interlevel insulation film as well as the first interconnect formation groove and the first dummy interconnect formation groove; and d) performing polishing by chemical mechanical polishing to the first metal film until the first interlevel insulation film is exposed, thereby forming a first interconnect of the first metal film in the first interconnect formation groove and a first dummy interconnect of the first metal film in the first dummy interconnect formation groove.

According to the method for fabricating a semiconductor device in accordance with the present invention, in the step d), when a first metal film is polished by chemical mechanical polishing until a first interlevel insulation film is exposed, the mechanical strength of an interlevel insulation film, which is a relatively small strength, can be increased. As a result, resistance against mechanical stress in polishing can be improved. Moreover, with the dummy interconnect provided in the interlevel insulation film, heat conductivity while the semiconductor element is in operation becomes excellent. Therefore, a long-term reliability of the semiconductor device is improved.

It is preferable that the method for fabricating a semiconductor device in accordance with the present invention further includes, between the steps a) and b), the steps of: e) forming, after a semiconductor element is formed on the semiconductor region, a lower layer interlevel insulation film so as to cover the semiconductor element; and f) selectively forming a contact plug in part of the lower interlevel insulation film located under the first dummy interconnect formation groove.

It is preferable that the method for fabricating a semiconductor device in accordance with the present invention further includes, after the step d), the steps of: g) forming a second interlevel insulation film of an insulator having a lower dielectric constant than a dielectric constant of silicon oxide over the first interlevel insulation film; h) selectively forming, in an upper portion of the second interlevel insulation film, a second interconnect formation groove and a second dummy interconnect formation groove so that the second dummy interconnect formation groove is located in the vicinity of the second interconnect formation groove; i) forming a second metal film over the second interlevel insulation film as well as the second interconnect formation groove and the second dummy interconnect formation groove; and j) performing polishing by chemical mechanical polishing to the second metal film until the second interlevel insulation film is exposed, thereby forming a second interconnect of the second metal film in the second interconnect formation groove and a second dummy interconnect of the second metal film in the second dummy interconnect formation groove.

It is preferable that the method for fabricating a semiconductor device in accordance with the present invention further includes, between the step d) and the step g), the steps of: k) forming a third interlevel insulation film of an insulator having a lower dielectric constant than a dielectric constant of silicon oxide; and 1) selectively forming a dummy connection section of a conductor in part of the third interlevel insulation film located under the second dummy interconnect formation groove so that the dummy connection section is connected to the first dummy interconnect. Thus, a second dummy interconnect can be made to have a so-called single damascene structure.

In the method for fabricating a semiconductor device in accordance with the present invention, it is preferable that in the step h), a dummy connection hole through which the first dummy interconnect is exposed is selectively formed in part of the second interlevel insulation film located under the second dummy interconnect formation groove. Thus, a second dummy interconnect can be made to have a so-called dual damascene structure.

It is preferable that the method for fabricating a semiconductor device in accordance with the present invention further includes the step m) of forming a pad electrode over the second dummy interconnect so that the pad electrode is electrically connected to the second dummy interconnect.

In the method for fabricating a semiconductor device in accordance with the present invention, it is preferable that the first interconnect and the first dummy interconnect are formed of a metal containing copper as a main component.

In the method for fabricating a semiconductor device in accordance with the present invention, it is preferable that the first interlevel insulation film is formed of silicon oxide containing carbon, fluorine and nitride.

### BRIEF DESCRIPTION OF THE DRAWINGS

FIG. 1 is a plan view illustrating a chip formation region in a semiconductor wafer forming a semiconductor device according to a first embodiment of the present invention.

FIG. 2 is a partial cross-sectional view illustrating the semiconductor device of the first embodiment of the present invention.

FIGS. 3A, 3B and 3C are cross-sectional views illustrating respective steps for fabricating the semiconductor device of the first embodiment of the present invention.

FIGS. 4A and 4B are cross-sectional views illustrating respective steps for fabricating the semiconductor device of the first embodiment of the present invention.

FIG. 5 is a partial cross-sectional view illustrating a semiconductor device according to a second embodiment of the present invention.

FIGS. 6A, 6B and 6C are partial cross-sectional views illustrating the semiconductor device of the second embodiment of the present invention.

FIG. 7 is a partial cross-sectional view illustrating a semiconductor device according to a first modified example of the second embodiment of the present invention.

FIG. 8 is a partial cross-sectional view illustrating a semiconductor device according to a second modified example of the second embodiment of the present invention.

FIG. 9 is a partial cross-sectional view illustrating a semiconductor device according to a third modified example of the second embodiment of the present invention.

FIG. 10A is a plan view illustrating a chip formation region in a semiconductor wafer forming a known semiconductor device. FIG. 10B is a partial enlarged plan view illustrating a corner portion shown in FIG. 10A.

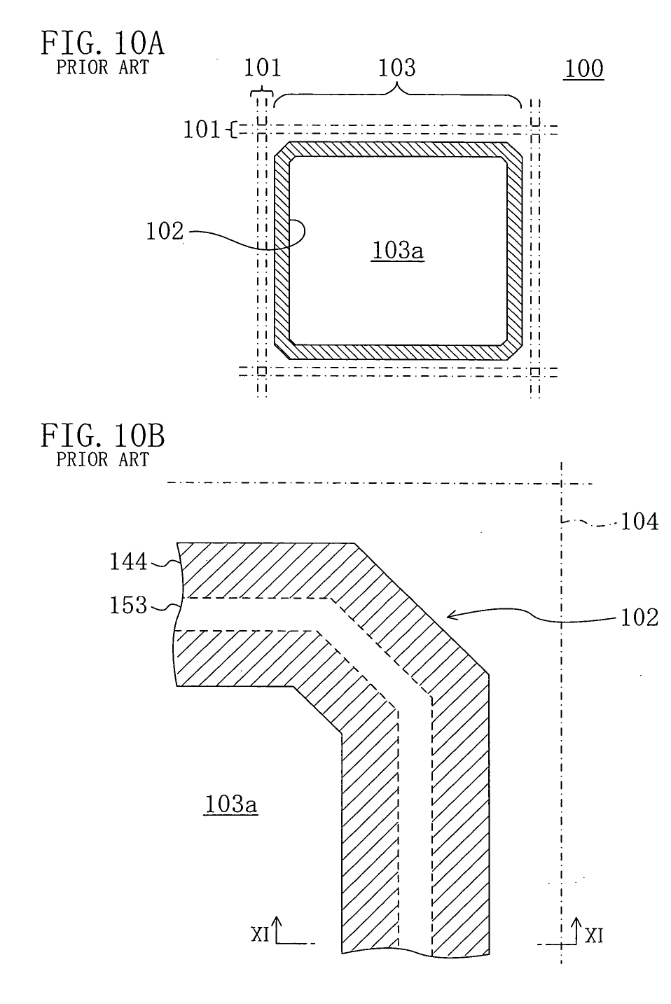

FIG. 11 is a cross-sectional view taken along the line IX-IX of FIG. 10.

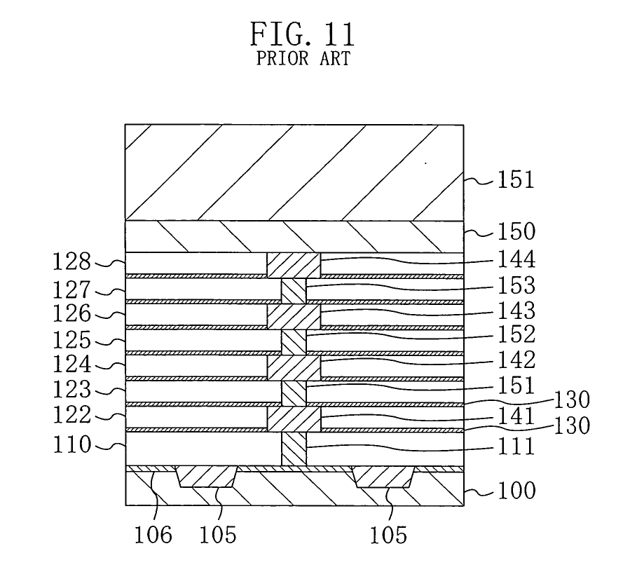

### BEST MODE FOR CARRYING OUT THE INVENTION

### First Embodiment

A first embodiment of the present invention will be described with reference to the accompanying drawings.

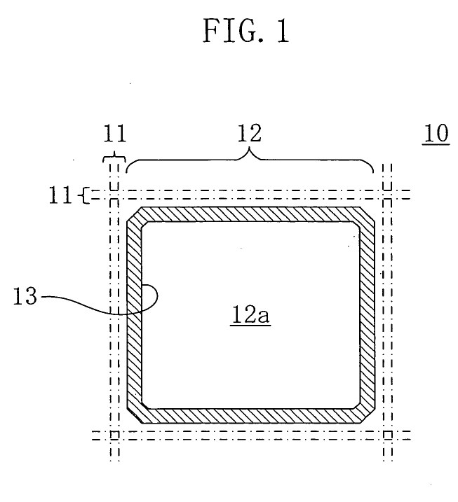

FIG. 1 is a view illustrating a planar structure of a chip formation region in a semiconductor wafer forming a semiconductor device according to the first embodiment of the present invention. As shown in FIG. 1, a chip region 12 is formed on a principal plane of a semiconductor substrate (semiconductor wafer) 10 so as to be surrounded by scribe regions 11 intersecting with one another. In an inner peripheral portion of the chip region 12, a seal ring 13 having a known structure is formed.

A semiconductor device according to the present invention is characterized in that a semiconductor element is provided in an element formation region 12a in part of the chip region 12 located inside of the seal ring 13.

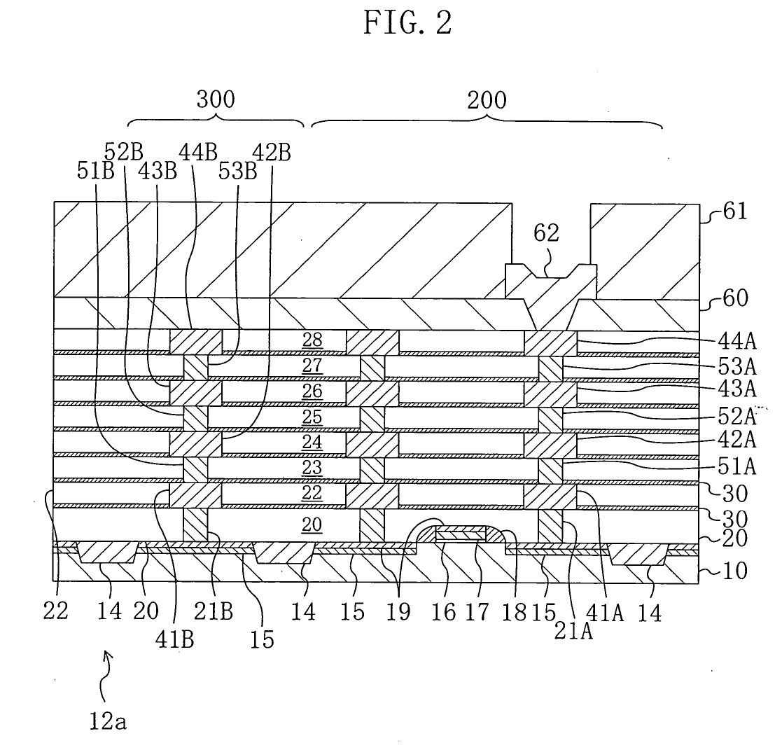

FIG. 2 is a view partially illustrating a cross-sectional structure of the semiconductor device of the first embodiment of the present invention. As shown in FIG. 2, the semiconductor device includes a plurality of isolation regions 14 selectively formed in upper part of the semiconductor substrate 10 formed of silicon (Si) and a plurality of active regions being isolated from one another by each of the isolation regions 14. The plurality of the active regions are formed so that each of the active regions lying astride a semiconductor element operation section 200 and a dummy interconnect section 300 located adjacent to the semiconductor element operation section 200.

Doped layers 15 are formed on parts of the semiconductor substrate 10 located in the active regions of the semiconductor element operation section 200, respectively, so as to be separated from one another and a gate electrode 17 of silicon is formed between adjacent ones of the doped layers 15 on the semiconductor substrate 10 with a gate insulation film 16 interposed between the gate electrode 17 and the semiconductor substrate 10. Sidewalls 18 are formed of an insulation film on both sides of the gate electrode 17, respectively. Thus, a field effect transistor (FET) including the gate electrode 17, the gate insulation film 16 and the doped layers 15 is formed.

In the FET, respective upper surfaces of the doped layers 15 and the gate electrode 17 are covered by a metal silicide layer 19 to be silicidized. A principal surface of the semiconductor substrate 10 in which upper surfaces of the doped regions 15 are silicidized is covered by a first interlevel insulation film 20 of, for example, silicon dioxide (SiO₂) as well as the FET.

Contact plugs 21A of, for example, tungsten (W) are formed in parts of the first interlevel insulation film 20 included in the semiconductor element operation section 200 and located over two of the doped layers 15, respectively. A second interlevel insulation film 22 is formed of, for example, silicon oxide containing carbon (SiOC) serving as a low dielectric constant insulation film so as to cover each of the contact plugs 21A with an etching stopper film 30 interposed between the second interlevel insulation film 22 and the first interlevel insulation film 20. In this case, the dielectric constant of SiOC is 3 or less, which is smaller than the dielectric constant of silicon dioxide (SiO₂), i.e., 3.9. First interconnects 41A each containing, for example, copper (Cu) as a main component are formed in parts of the second interlevel insulation film 22 located on the contact plugs 21A, respectively. The first interconnects 41A are covered by a third interlevel insulation film 23 of SiOC and first connection sections (via) 51A each containing Cu as a main component are formed in parts of the third interlevel insulation film 23 located on the first interconnect 41A. Furthermore, second interconnects 42A, third interconnects 43A, and fourth interconnects 44A are formed over the first connection sections 51A with a second connection section 52A interposed between each of the second interconnects 42A and an associated one of the third interconnects 43A and a third connection section 53A interposed between each of the third interconnects 43A and an associated one of the fourth interconnects 44A.

In this case, the second interconnects 42A are formed in the fourth interlevel insulation film 24 of SiOC, the second interconnects 52A are formed in the fifth interlevel insulation film 25 of SiOC, the third interconnects 43A are formed in the sixth interlevel insulation film 26 of SiOC, the third interconnects 53A are formed in the seventh interlevel insulation film 27 of SiOC, and the fourth interconnects 44A are formed in the eighth interlevel insulation film 28 of SiOC.

On the other hand, a dummy contact plug 21B is formed of, for example, W on part of the first interlevel insulation film 20 included in the dummy interconnect section 300 and located over the doped layer 15. In the second interlevel insulation film 22 formed of SiOC and covering the dummy contact plug 21B, a first dummy interconnect 41B containing Cu as a main component is formed so as to be connected to the dummy contact plug 21B. Over the first dummy interconnect 41B, second, third and fourth dummy interconnects 42B, 43B and 44B are formed with a first connection section 51B interposed between the first dummy interconnect 41B and the second dummy interconnect 42B, a second connection section 52B interposed between the second dummy interconnect 42B and the third dummy interconnect 43B, and a third connection section 53B interposed between the third dummy interconnect 43B and the fourth dummy interconnect 44B. In this case, each of the first, second, third and fourth dummy interconnects 41B, 42B, 43B and 44B has a length of 100 μm or less and, specifically, a length of μm in the first embodiment.

On the eighth interlevel insulation film 28, a moisture-resistant insulation film 60 of, for example, silicon nitride (SiN) is formed. A protection film 61 of polyimide is formed on the moisture-resistant insulation film 60.

Moreover, a pad electrode 62 is formed in the protection film 61 and the moisture-resistant insulation film 60 so as to be connected to one of the two fourth interconnects 44A.

Hereinafter, a method for fabricating a semiconductor device having the above-described structure will be described with reference to the accompanying drawings.

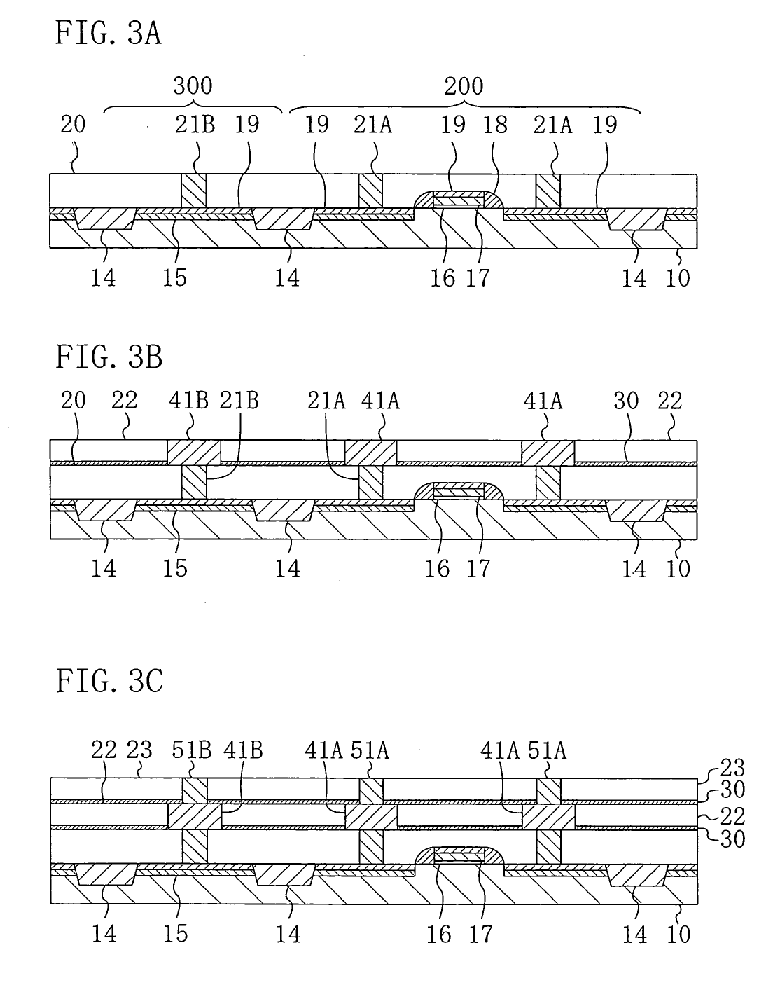

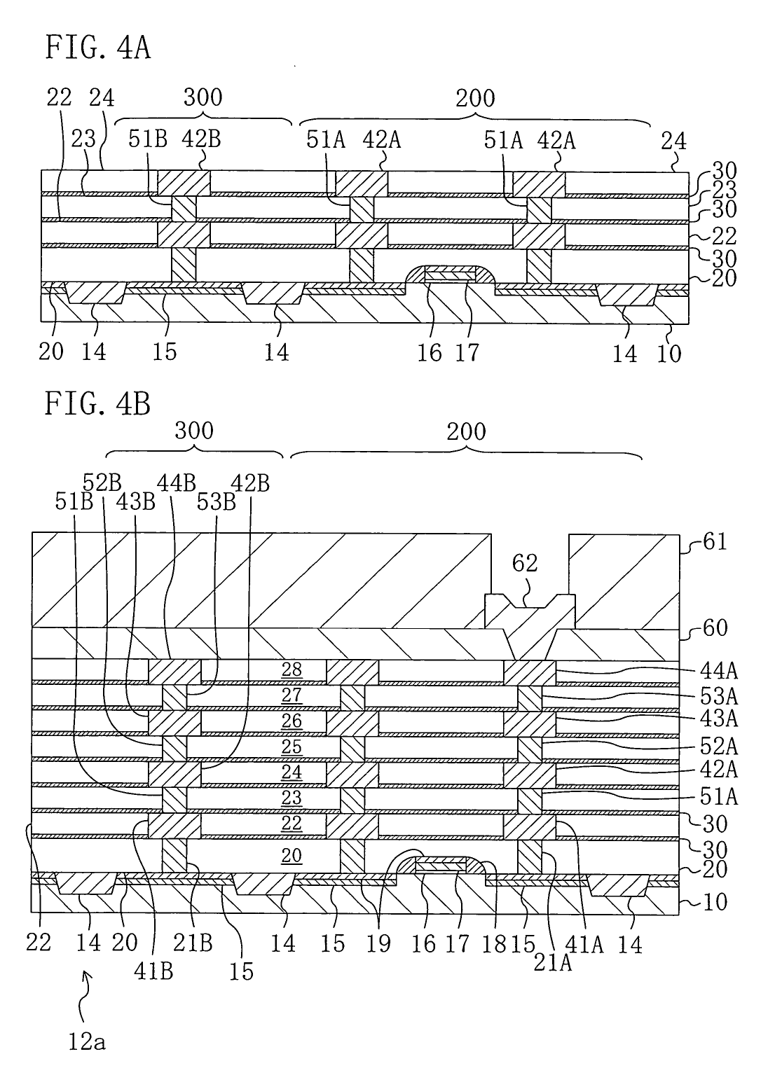

FIGS. 3A, 3B and 3C and FIGS. 4A and 4B are cross-sectional views illustrating respective steps for fabricating the semiconductor device of the first embodiment of the present invention.

First, as shown in FIG. 3A, shallow trench isolation (STI) is performed to selectively form isolation regions 14 on a principal surface of a semiconductor substrate 10. Thus, active regions are formed so that each of the active regions is surrounded by the isolation regions 14. Subsequently, thermal oxidation is performed to form a gate insulation film 16 on at least part of a principal surface of the semiconductor substrate 10 located over a semiconductor isolation operation section 200 so as to have a thickness of, for example, 2 nm. Then, a polysilicon film is deposited over the gate insulation film 16 to a thickness of about 200 nm by chemical vapor deposition (CVD). Thereafter, using lithography and reactive ion etching (RIE), the polysilicon film is etched so that a gate electrode 17 is formed of the polysilicon film. Then, a TEOS (tetra-ethyl-ortho-silicate) film and a silicon nitride film are deposited in this order over the semiconductor substrate 10 to a thickness of about 13 nm and a thickness of about 60 nm, respectively, so as to cover the gate electrode 17. Thereafter, a resultant lamination film is etched back to form sidewalls 18 on both sides of the gate electrode 17, respectively, so as to have a width of about 55 nm. Subsequently, using the gate electrode 17 and the sidewalls 18 as a mask, ion implantation into each of the active regions of the semiconductor substrate 10 is performed to form, for example, n-type doped layers 15. Thereafter, a metal film such as titanium (Ti), cobalt (Co) and the like are deposited over a principal surface of the semiconductor substrate 10 by silicide formation and then thermal treatment is performed to form a metal silicide layer 19 on an exposed surface of each of the doped layers 15 and the gate insulation film 17 over the semiconductor substrate 10.

Subsequently, a first interlevel insulation film 20 of silicon oxide is deposited to a thickness of about 1000 nm over the principal surface of the semiconductor substrate 10 on which the metal silicide layer 19 is formed. Then, chemical mechanical polishing (CMP) is performed to planarize an upper surface of the first interlevel insulation film 20. Thereafter, a resist mask (not shown) formed by lithography so as to have an opening for forming a contact hole over each of the silicidized doped layers 15. Subsequently, dry etching is performed using the resist mask, thereby forming contact holes in the first interlevel insulation film 20. After the resist mask is removed, titanium (Ti) and titanium nitride (TiN) are deposited in this order on the first interlevel insulation film 20 by CVD to a thickness of about 10 nm and a thickness of about 5 nm, respectively, to form a lamination film (not shown) for improving adhesion between tungsten and the first interlevel insulation film 20. Thereafter, a tungsten film is deposited over the lamination film to a thickness of about 200 nm by CVD. Then, the lamination film and the tungsten film deposited over the first insulation interlevel insulation film 20 are removed, thereby forming contact plugs 21A in ones of the contact holes located in a semiconductor element operation section 200 and a dummy contact plug 21B in one of the contact holes located in the dummy interconnect section 300.

Next, as shown in FIG. 3B, an etching stopper film 30 of silicon oxynitride (SiON) is deposited over the first interlevel insulation film 20 to a thickness of about 30 nm by CVD. Subsequently, a second interlevel insulation film 22 of silicon oxide containing carbon (SiOC) is deposited over the etching stopper film 30 to a thickness of about 250 nm by CVD. Thereafter, by lithography and dry etching using an etching gas containing C₄F₈ or CF₄ as a main component, grooves for forming first interconnect and a first dummy interconnect are formed so that the contact plugs 21A are exposed through the first interconnect formation grooves and the dummy contact plug 21B is exposed through the first dummy interconnect formation groove. Subsequently, tantalum nitride (TaN) and tantalum (Ta) are deposited in this order to a thickness of about 10 nm and a thickness of about 25 nm, respectively, by sputtering to form a barrier film (not shown) for preventing diffusion of copper atoms constituting a metal interconnect. Thereafter, field plating is performed to deposit a metal film containing copper as a main component over the barrier film to a thickness of about 600 nm. Subsequently, the metal film and the barrier film are polished by CMP until the second interlevel insulation film 22 is exposed, so that first interconnects 41A are formed in ones of the grooves in the semiconductor element operation section 200 and a first dummy interconnect 41B is formed in one of the grooves in the dummy interconnect section 300. Each of the first interconnects 41A and the first dummy interconnect 41B includes the barrier film and the metal film stacked therein.

Next, as shown in FIG. 3C, an etching stopper film 30 of silicon oxynitride is deposited over the second interlevel insulation film 22 to a thickness of about 30 nm by CVD, and then a third interlevel insulation film 23 of SiOC is deposited over the etching stopper film 30 to a thickness of about 250 nm. Thereafter, by lithography and dry etching, grooves for forming first connection sections and a first dummy connection section are formed in the third interlevel insulation film 23 so that the first interconnects 41A are exposed through the first connection section formation grooves, respectively, and the first dummy interconnect 41B is exposed through the first dummy connection section formation groove. Subsequently, TaN and Ta are deposited in this order to a thickness of about 10 nm and a thickness of about 25 nm, respectively, by sputtering to form a barrier film (not shown). Thereafter, field plating is performed to deposit a metal film containing copper as a main component over the barrier film to a thickness of about 600 nm. Subsequently, the metal film and the barrier film are polished by CMP until the third interlevel insulation film 23 is exposed, so that in the interlevel insulation film 23, first connection sections 51A are formed in ones of the grooves located in the semiconductor element operation section 200 and a first dummy connection section 51B is formed in one of the grooves located in the dummy interconnect section 300. Each of the first connection sections 51A and the first dummy connection section 51B includes the barrier film and the metal film stacked therein.

Next, as shown in FIG. 4A, an etching stopper film 30 of SiON and a fourth interlevel insulation film 24 of SiOC are deposited over the third insulation film and, furthermore, fourth interlevel insulation films 24, second interconnects 42A and a second dummy interconnect 42B are formed in the same manner as the first interconnects 41A and the first dummy interconnects 41B.

Next, as shown in FIG. 4B, in the same manner as described above, fourth interconnects 44A and a fourth dummy interconnect 44B are formed in an eight interlevel insulation film 28. Subsequently, a moisture-resistant insulation film 60 of SiN is deposited over the eighth interlevel insulation film 28 to a thickness of about 300 nm by CVD. Thereafter, by lithography and dry etching using an etching gas containing fluorocarbon as a main component, an opening is formed so as to correspond part of the moisture-resistant insulation film 60 through which one of the fourth interconnects 44A is exposed. Subsequently, Ti, TiN and Aluminum (Al) are deposited in this order over an entire upper surface of the moisture-resistant insulation film 60 as well as the opening to a thickness of 30 nm, 100 nm and 800 nm, respectively, to form a metal lamination film. Then, by lithography and dry etching using an etching gas containing chlorine as a main component, the metal lamination film is etched and patterning is performed to form a pad electrode 62. Thereafter, a protection film 61 of polyimide is formed over the moisture-resistant insulation film 60 by spin coating and an opening is formed in part of the protection film 61 located over the pad electrode 62.

Thus, according to the fabrication method of the first embodiment, in forming the plurality of interconnect layers 41A through 44A, each of the first, second and third connection sections 41B, 42B and 43B is provided between ones of the interconnect layers 41A through 44A located adjacent to each other in the vertical direction and, therefore, seven interlevel insulation films, i.e., the second through eighth interlevel insulation films 22 through 28 are necessary. Each of the second through eighth interlevel insulation films 22 through 28 is a low dielectric constant insulation film and its chemical stability, mechanical strength, adhesion and thermal stability are poor, compared to silicon oxide. In the first embodiment, as shown in FIG. 1, the dummy interconnect section 300 is provided in part of the semiconductor substrate 10 located inside of the seal ring 13, i.e., the device formation region 12a so as to be adjacent to the semiconductor element operation section 200 including a semiconductor element such as a FET. Thus, even if a mechanical stress is applied to the second through eighth interlevel insulation films 22 through 28 in polishing using CMP, for example, the mechanical strength of the interlevel insulation film 22 is improved due to the first dummy interconnect 41B.

Furthermore, the first dummy interconnect 41B is connected to one of the doped layers 15 silicidized and located in the semiconductor substrate 10 with the dummy contact 21B interposed therebetween, so that not only the mechanical strength is improved but also heat generated while the semiconductor element is in operation can be conducted to the semiconductor substrate 10. Specifically, according to the first embodiment, resistance against mechanical stress in polishing is increased, so that the yield is improved and heat conductivity while the semiconductor element is in operation becomes excellent. Therefore, a long-term reliability of the semiconductor device is improved.

Note that in this embodiment, as a low dielectric constant insulator, silicon oxide containing carbon (SiOC) is used. However, the present invention is not limited thereto, but silicon oxide containing fluorine (FSG, SiOF) or silicon oxynitride (SiON) may be used as a low dielectric constant insulator.

Moreover, for the etching stopper film 30, silicon oxynitride is used in this embodiment but silicon carbide (SiC) or silicon nitride (SiN) may be used.

Moreover, the moisture-resistant insulation film 60 serving as a passivation film is not limited to a single layer film of silicon nitride but, for example, may have a laminated structure of silicon nitride and silicon oxide.

Moreover, in the first embodiment, four interconnect layers are provided. However, the present invention is applicable to a semiconductor device in which one or more interconnect layer(s) is provide.

### Second Embodiment

Hereinafter, a second embodiment of the present invention will be described with reference to the accompanying drawings.

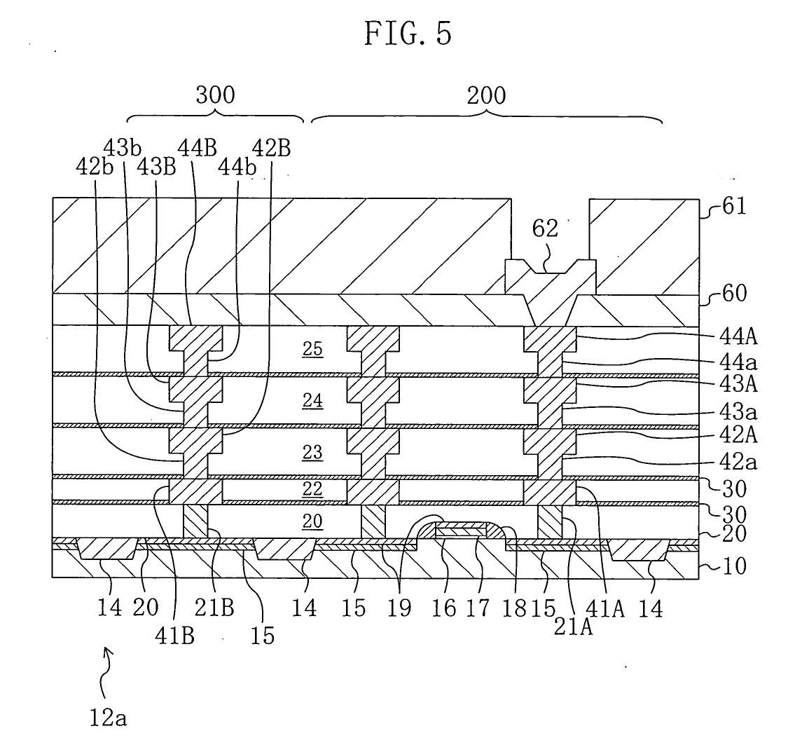

FIG. 5 is a view partially illustrating a cross-sectional structure of a semiconductor device according to a second embodiment of the present invention. In FIG. 5, each member also shown in FIG. 2 is identified by the same reference numeral and therefore the description thereof will be omitted.

The multilayer interconnect of the first embodiment as well as the dummy interconnect section 300 is formed by so-called single damascene in which an interconnect layer and a connection section (via) are separately formed. In the second embodiment, in contrast, dual damascene in which an interconnect layer and a connection section are formed as a unit is used to form the multilayer interconnect.

A mechanical stress generated in polishing the second interlevel insulation film 22 of a low dielectric constant material and the like by CMP is different between single damascene in the first embodiment and dual damascene in the second embodiment. Therefore, it is preferable to select one of these two methods in consideration of a tolerance for a stress applied to a low dielectric constant insulation film.

Furthermore, as a characteristic of dual damascene, the number of process steps can be reduced, compared to single damascene. This has to be also taken into consideration.

As shown in FIG. 5, for example, in a third interlevel insulation film 23 of SiOC, second interconnects 42A and first connection sections 42a each of which is formed as a unit with an associated one of the second interconnects 42A are provided in the semiconductor element operation section 200, and a second dummy interconnect 42B and a first dummy connection section 42b formed as a unit with the second dummy interconnect 42B are provided in the dummy interconnect formation section 300.

In a fourth interlevel insulation film 24, third interconnects 43A and second connection sections 43a each of which is formed as a unit with an associated one of the third interconnects 43A are provided, and also a third dummy interconnect 43B and a second dummy connection section 43b as a unit with the third dummy interconnect 43B are provided. In the same manner, in a fifth interlevel insulation film 25, fourth interconnects 44A and third connection sections 44a each of which is formed as a unit with an associated one of the fourth interconnects 44A are formed, and also a fourth interconnect 44B and a third dummy connection section 44b formed as a unit with the fourth interconnect 44B are formed.

Hereinafter, a method for fabricating a semiconductor device formed so as to have the above-described structure will be described with reference to the accompanying drawings.

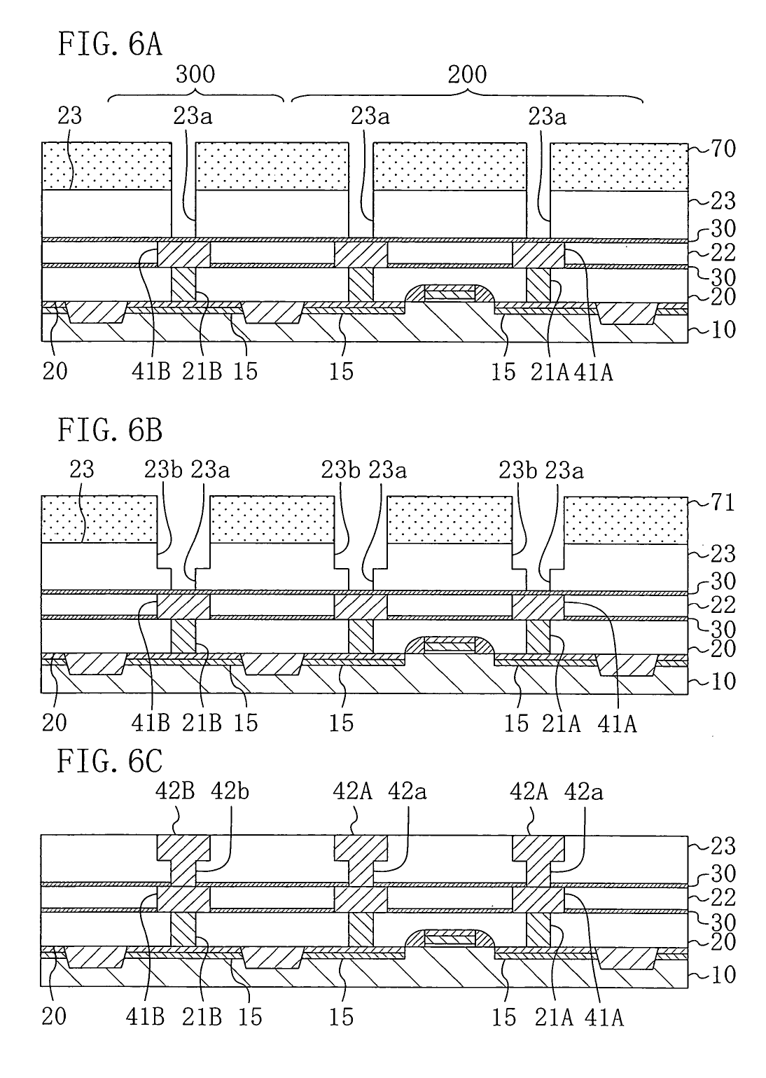

FIGS. 6A through 6C are cross-sectional views illustrating respective steps for fabricating the semiconductor device of the second embodiment of the present invention.

First, as shown in FIG. 6A, a FET including doped regions 15 in parts of the semiconductor substrate 10 located in the semiconductor element operation section 200 is formed and a doped region 15 is formed in part of the semiconductor substrate 10 located in the dummy interconnect section 300 in the same manner as in the first embodiment. Subsequently, a first interlevel insulation film 20 of silicon oxide, contact plugs 21A and a dummy contact plug 21B are formed. Thereafter, an etching stopper film 30 of SiON and a second interlevel insulation film 22 of, for example, SiOC are formed in this order. Subsequently, first interconnects 41A are formed in parts of the second interlevel insulation film 20 located over the contact plugs 21A, respectively, and a first dummy interconnect 41B is formed in part of the second interlevel insulation film 22 located over the dummy contact plug 21B. Then, an etching stopper film 30 of SiON is deposited over the second interlevel insulation film 22 to a thickness of about 30 nm by CVD. Subsequently, a third interlevel insulation film 23 of SiOC is deposited over the etching stopper film 30 to a thickness of about 500 nm by CVD. Thereafter, a first resist mask 70 is formed by lithography so as to have openings over the first interconnects 41A and the first dummy interconnect 41B, respectively. Subsequently, dry etching is performed to the third interlevel insulation film 23 using the first resist mask 70, thereby forming contact holes 23a for forming first connection sections through which the first interconnects 41A are exposed, respectively, and a first dummy connection section through which the first dummy interconnect 41B is exposed.

Next, as shown in FIG. 6B, after the first resist mask 70 has been removed, a second resist mask 71 is formed over the third interlevel insulation film 23 so as to have an opening pattern with openings for forming interconnects corresponding to regions of the third interlevel insulation film 23 including the contact holes 23a. Subsequently, dry etching is performed to the third interlevel insulation film 23 using the second resist mask 71 to form grooves 23b for forming second interconnects and a second dummy interconnect.

Next, as shown in FIG. 6C, TaN and Ta are deposited in this order to a thickness of about 10 nm and a thickness of about 25 nm, respectively, to form a barrier film (not shown). Thereafter, field plating is performed to deposit a metal film containing copper as a main component over the barrier film to a thickness of about 800 nm. Subsequently, the metal film and the barrier film are polished by CMP until the third interlevel insulation film 23 is exposed, so that the second interconnects 42A each of which includes an associated one of the first connection portions 42a and in which the barrier film and the metal film are stacked are formed in ones of the grooves located in the semiconductor element operation section 200 in the third interlevel insulation film 23, respectively. At the same time, the second dummy interconnect 42B including the first dummy connection section 42b is formed in one of the grooves located in the dummy interconnect section 300 in the third interlevel insulation film 23.

Next, in the same manner as described above, third interconnects 43A each including an associated one of second connection sections 43a and a third dummy interconnect 43B including a second dummy connection section 43b are formed in the fourth interlevel insulation film 24. Furthermore, fourth interconnects 44A each including an associated one of third connection sections 44a and a fourth dummy interconnect 44B including a third dummy connection section 44b are formed in the fifth interlevel insulation film 25. Subsequently, a moisture-resistant insulation film 60, a pad electrode 62 and a protection film 61 are formed over the fifth interlevel insulation film 25. Thus, the semiconductor device of FIG. 5 is obtained.

Thus, according to the second embodiment, resistance against mechanical stress in polishing performed to the second through fifth interlevel insulation films 22 through 25 of a low dielectric constant insulator is increased, so that the yield is improved and heat conductivity while the semiconductor element is in operation becomes excellent due to the dummy interconnects 41B through 44B. Therefore, a long-term reliability of the semiconductor device is improved.

### First Modified Example of Second Embodiment

Hereinafter, a first modified example of the second embodiment of the present invention will be described with reference to the accompanying drawings.

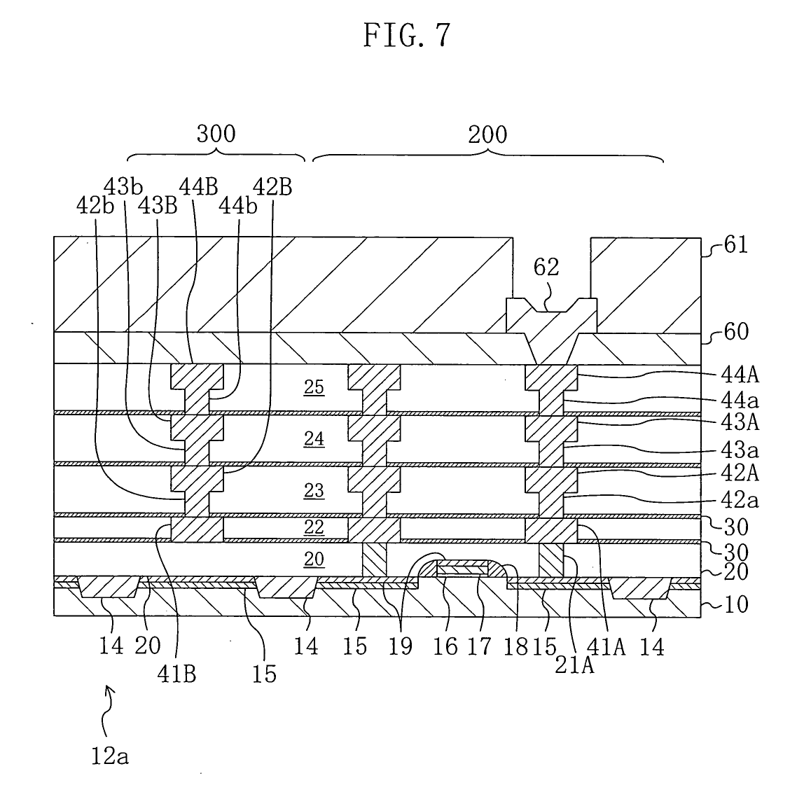

FIG. 7 is a view partially illustrating a cross section of a semiconductor device according to the first modified example of the second embodiment of the present invention. In FIG. 7, each member also shown in FIG. 5 is identified by the same reference numeral and therefore the description thereof will be omitted.

As shown in FIG. 7, in the first modified example, a dummy contact is not formed between a first dummy interconnect 41B and a semiconductor substrate 10. That is, the first through fourth interconnects 41B through 44B are electrically floating.

Thus, with a dummy contact not provided in a dummy interconnection section 300, the degree of freedom of circuit design is improved and increase in a chip area can be suppressed.

### Second Modified Example of Second Embodiment

Hereinafter, a second modified example of the second embodiment of the present invention will be described with reference to the accompanying drawings.

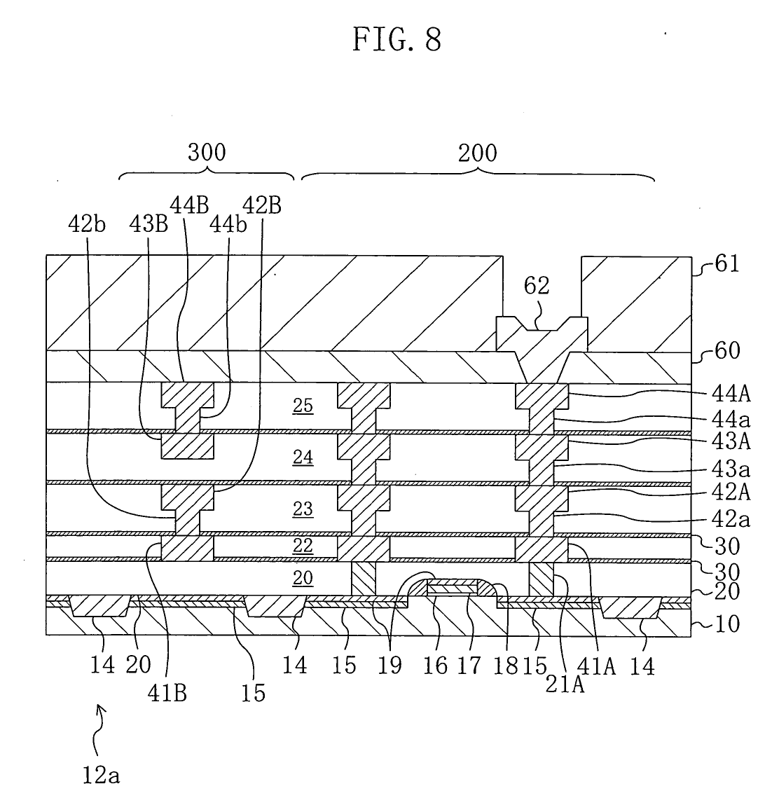

FIG. 8 is a view partially illustrating a cross section of a semiconductor device according to the second modified example of the second embodiment of the present invention. In FIG. 8, each member also shown in FIG. 5 is identified by the same reference numeral and the description thereof will be omitted.

As shown in FIG. 8, in the second modified example, not only a dummy contact is not provided but also a second connection portion between the second dummy interconnect 42B and a third dummy interconnect 43B is not provided in the third dummy interconnect 43B.

Thus, with a dummy contact and a second connection section not provided in the dummy interconnect section 300, the degree of freedom is improved and increase in a chip area can be suppressed.

### Third Modified Example of Second Embodiment

Hereinafter, a third modified example of a second embodiment of the present invention will be described with reference to the accompanying drawings.

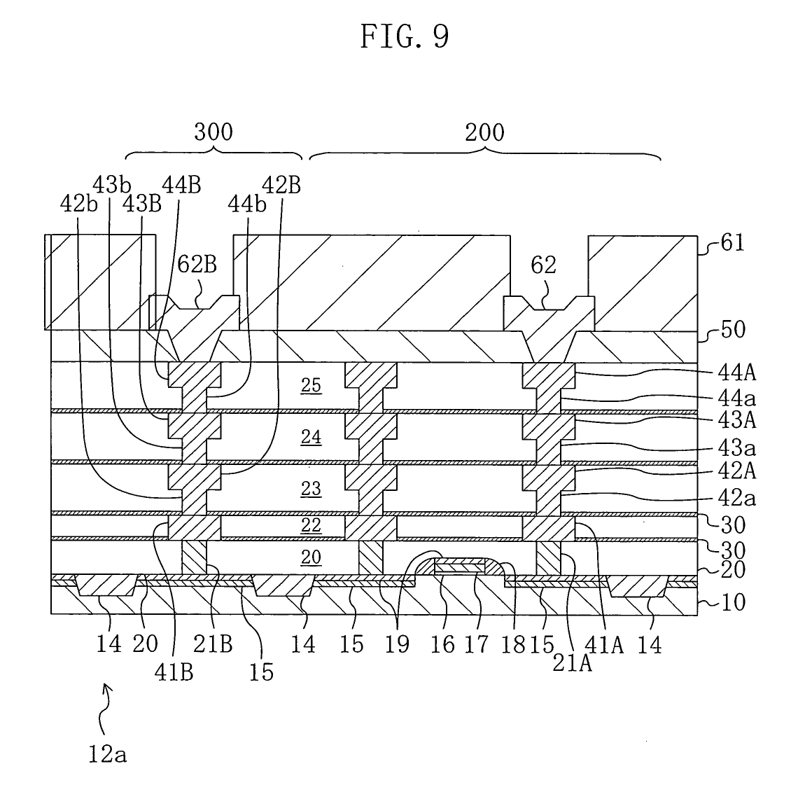

FIG. 9 is a view partially illustrating a cross section of a semiconductor device according to the third modified example of the second embodiment of the present invention. In FIG. 9, each member also shown in FIG. 5 is identified by the same reference numeral and the description thereof will be omitted.

As shown in FIG. 9, in the semiconductor device of the third modified example, a dummy pad electrode 62B is formed on a fourth dummy interconnect 44B so as to be connected to the dummy interconnect 44B in a dummy interconnect portion 300.

Thus, heat generated from a semiconductor element operation section 200 can be effectively released to the outside through each of dummy interconnects 41B through 44B, dummy connection sections 42b, 43b and 44b, and the dummy electrode 62B. Furthermore, when wire bonding is performed to the dummy pad electrode 62B, heat can be more effectively released.

As has been described, the present invention has the effect of improving resistance against chemical stress in polishing a low dielectric constant insulation film and also the effect of increasing thermal conductivity when a semiconductor device is in operation, Therefore, the present invention is useful to a semiconductor device using a low dielectric constant insulation film as an interlevel insulation film between interconnects in a multilayer interconnect structure and a method for fabricating the semiconductor device.

What is claimed is:

1. A semiconductor device comprising:
a semiconductor element formed on a semiconductor region;
a first interconnect formed over the semiconductor region and electrically connected to the semiconductor element;
a second interconnect formed over the first interconnect with an interlevel insulation film made of an insulator having a lower dielectric constant than a dielectric constant of silicon oxide interposed between the first interconnect and the second interconnect; and
a first dummy interconnect formed on part of the semiconductor region located in the vicinity of the first interconnect or the second interconnect.

2. The semiconductor device of claim 1, further comprising a contact plug for connecting the first dummy interconnect and the semiconductor region.

3. The semiconductor device of claim 1, further comprising a pad electrode electrically connected with the first dummy interconnect.

4. The semiconductor device of claim 1, wherein the first dummy interconnect is formed along the first interconnect or the second interconnect and the length of a side of the first dummy interconnect is 100 μm or less.

5. The semiconductor device of claim 1, wherein the first dummy interconnect is formed by the side of the first interconnect so as to be located adjacent to the first interconnect, and
wherein the semiconductor device further includes a second dummy interconnect formed over the first dummy interconnect with an interlevel insulation film interposed between the first dummy interconnect and the second dummy interconnect.

6. The semiconductor device of claim 5, wherein the first dummy interconnect and the second dummy interconnect are connected to each other via a dummy connection section.

7. The semiconductor device of claim 6, wherein the second interconnect and a connection portion for connecting the first interconnect and the second interconnect are formed as a unit and the second dummy interconnect and the dummy connection portion are formed as a unit.

8. The semiconductor device of claim 1, wherein the first dummy interconnect is electrically floating.

9. The semiconductor device of claim 1, wherein the first interconnect, the second interconnect and the first dummy interconnect are formed of a metal containing copper as a main component.

10. The semiconductor device of claim 1, wherein the interlevel insulation film is formed of silicon oxide containing carbon, fluorine or nitride.

11. The semiconductor device of claim 1, wherein the first dummy interconnect is formed in the inside of a seal ring formed along an inner peripheral portion of a scribe region of the semiconductor region.

12. A method for fabricating a semiconductor device, the method comprising the steps of:
a) forming, on a semiconductor region, a first interlevel insulation film of an insulator having a lower dielectric constant than a dielectric constant of silicon oxide;
b) selectively forming, in an upper portion of the first interlevel insulation film, a first interconnect formation groove and a first dummy interconnect formation groove so that the first dummy interconnect formation groove is located in the vicinity of the first interconnect formation groove;
c) forming a first metal film over the first interlevel insulation film as well as the first interconnect formation groove and the first dummy interconnect formation groove; and
d) performing polishing by chemical mechanical polishing to the first metal film until the first interlevel insulation film is exposed, thereby forming a first interconnect of the first metal film in the first interconnect formation groove and a first dummy interconnect of the first metal film in the first dummy interconnect formation groove.

13. The method of claim 12, further comprising, between the steps a) and b), the steps of:
e) forming, after a semiconductor element is formed on the semiconductor region, a lower layer interlevel insulation film so as to cover the semiconductor element; and
f) selectively forming a contact plug in part of the lower interlevel insulation film located under the first dummy interconnect formation groove.

14. The method of claim 12, further comprising, after the step d), the steps of:
g) forming a second interlevel insulation film of an insulator having a lower dielectric constant than a dielectric constant of silicon oxide over the first interlevel insulation film;
h) selectively forming, in an upper portion of the second interlevel insulation film, a second interconnect formation groove and a second dummy interconnect formation groove so that the second dummy interconnect formation groove is located in the vicinity of the second interconnect formation groove;
i) forming a second metal film over the second interlevel insulation film as well as the second interconnect formation groove and the second dummy interconnect formation groove; and
j) performing polishing by chemical mechanical polishing to the second metal film until the second interlevel insulation film is exposed, thereby forming a second interconnect of the second metal film in the second interconnect formation groove and a second dummy interconnect of the second metal film in the second dummy interconnect formation groove.

15. The method of claim 14, further comprising, between the step d) and the step g), the steps of:
k) forming a third interlevel insulation film of an insulator having a lower dielectric constant than a dielectric constant of silicon oxide; and
l) selectively forming a dummy connection section of a conductor in part of the third interlevel insulation film located under the second dummy interconnect formation groove so that the dummy connection section is connected to the first dummy interconnect.

16. The method of claim 14, wherein in the step h), a dummy connection hole through which the first dummy interconnect is exposed is selectively formed in part of the second interlevel insulation film located under the second dummy interconnect formation groove.

17. The method of claim 12, further comprising the step m) of forming a pad electrode over the second dummy interconnect so that the pad electrode is electrically connected to the second dummy interconnect.

18. The method of claim 12, wherein the first interconnect and the first dummy interconnect are formed of a metal containing copper as a main component.

19. The method of claim 12, wherein the first interlevel insulation film is formed of silicon oxide containing carbon, fluorine and nitride.
